(19) United States
(12) Patent Application Publication
(10) Pub. No.: US 2025/0311093 A1
(43) Pub. Date: Oct. 2, 2025

(54) INTEGRATED DEVICE HAVING A COAXIAL STRUCTURE

(71) Applicant: TEXAS INSTRUMENTS INCORPORATED, DALLAS, TX (US)

(72) Inventors: Claudia VASANELLI, MUNICH (DE); Mohammad VATANKHAH VARNOOSFADERANI, DALLAS, TX (US); Siraj AKHTAR, RICHARDSON, TX (US); Brian GINSBURG, ALLEN, TX (US)

(21) Appl. No.: 18/622,941

(22) Filed: Mar. 31, 2024

(51) Int. Cl. H05K 1/02; H01L 23/498; H01Q 1/22; H05K 1/11

(52) U.S. Cl. CPC H05K 1/0243; H01L 23/49816; H01L 23/49838; H01Q 1/22; H05K 1/115; H05K 2201/10098

(57) ABSTRACT

Integrated devices having a coaxial structure are described. In one example, an integrated device includes a package substrate and a first coaxial structure. The package substrate includes an integrated die and a signal launch configured to emit or receive a signal. The first coaxial structure is arranged partially on a surface of the package substrate. The first coaxial structure includes an inner coaxial conductor electrically coupled to the signal launch and an outer coaxial conductor comprising an array of grounded conductors arranged to at least partially surround the inner coaxial conductor. The first coaxial structure is adapted to be coupled to a second coaxial structure of a PCB via the surface of the package substrate.

### TECHNICAL FIELD

This description relates to reducing the footprint of an integrated device, such as a launch on package, using a coaxial structure.

### BACKGROUND

In semiconductor industries, demands for miniaturization have accelerated the development of smaller integrated devices. The demand for the packaging or interconnecting techniques in such high-density integrated devices has also increased in order to accommodate other integrated devices. For example, systems using antennas with packaged integrated devices often place the antennas on a substrate such as those used for a printed circuit board, an organic substrate, or other low dielectric substrate that is mounted to a package substrate. These approaches often employ expensive printed circuit board (PCB) substrates, which are sometimes used inside the integrated package with mold compound covering the semiconductor devices. These solutions are relatively high in cost and require substantial device area.

### SUMMARY

In one example, an integrated device includes a package substrate and a first coaxial structure. The package substrate includes an integrated die and a signal launch configured to emit or receive a signal. The first coaxial structure is arranged partially on a surface of the package substrate. The first coaxial structure includes an inner coaxial conductor electrically coupled to the signal launch and an outer coaxial conductor comprising an array of grounded conductors arranged to at least partially surround the inner coaxial conductor. The first coaxial structure is adapted to be coupled to a second coaxial structure of a PCB via the surface of the package substrate.

In another example, an antenna system includes a PCB comprising a signal via and a plurality of grounded vias extending through the PCB to an antenna. The antenna system also includes an integrated package having a package substrate, an inner coaxial conductor, and an outer coaxial conductor. The package substrate is mounted to the PCB and comprising an integrated die and a signal launch configured to emit or receive a signal. The inner coaxial conductor is affixed to the package substrate and electrically coupled to the signal launch and to the signal via of the PCB. The outer coaxial conductor includes an array of grounded conductors affixed to the package substrate and electrically coupled to the respective grounded vias of the PCB.

In yet another example, a device includes a package substrate and a coaxial structure. The package substrate comprises an integrated die and a signal launch on the package substrate. The signal launch is configured to emit or receive a signal. The coaxial structure includes a ball grid array (BGA) affixed to the package substrate. The BGA comprises an inner coaxial conductor including a signal solder ball electrically coupled to the signal launch and an outer coaxial conductor comprising a set of grounded solder balls arranged to at least partially surround the inner coaxial conductor.

In a further example, an integrated device includes a PCB having an outer coaxial conductor at least partially surrounding an inner coaxial conductor to form a PCB coaxial structure. The PCB coaxial structure is adapted to be coupled to a package substrate coaxial structure arranged partially on a surface of a package substrate.

### BRIEF DESCRIPTION OF THE DRAWINGS

FIG. 1 illustrates an example of an integrated device having a coaxial structure adapted to couple with a corresponding coaxial structure of a PCB substrate.

FIG. 2 illustrates an example of a side view of an integrated device having a coaxial structure and a PCB substrate having a corresponding coaxial structure.

FIG. 3 illustrates an example of a top view of the integrated device, of FIG. 2, including a signal launch.

FIG. 4 illustrates an example of a side view of an integrated device, having a coaxial structure, a PCB substrate, having a corresponding coaxial structure, and an antenna system.

FIG. 5 illustrates an example of an antenna system with a waveguide interface having an L-shaped coupler.

FIG. 6 illustrates an example of an antenna system with a waveguide interface having a stepped ridge coupler.

FIG. 7A illustrates an example of an antenna system with a waveguide interface having a linear coupler.

FIG. 7B illustrates another example of an antenna system with a transmission line having a linear coupler.

FIG. 8 illustrates an example of an antenna system with a coupler extending through a void in a PCB substrate to feed the antenna system.

FIG. 9 illustrates an example of an integrated device having a plurality of coaxial structures.

FIG. 10 illustrates an example of a ball map for a plurality of an integrated devices.

### DETAILED DESCRIPTION

Forming compact and cost-effective integrated devices, such as devices with antennas, remains challenging. Typically, utilizing an antenna on an integrated device increases the footprint of the integrated device and the manufacturing cost thereof. When adequate space is not available, the capability of the integrated device is sacrificed. In some examples, conventional launch-on-package (LOP) devices utilize a rectangular cross-sectional waveguide implemented in a printed circuit board (PCB) through first milling (or drilling) and then metal coating with waveguide walls. The waveguide implemented in the conventional PCB has a lower frequency limit based on the geometry of the rectangular waveguide. Furthermore, the relatively large size of waveguide and, consequently, the relatively large footprint of the waveguides on the integrated device, limits the number of signals that can be transmitted and/or received in a given one of the conventional integrated devices.

The systems and methods herein provide an integrated device with a coaxial structure to reduce the footprint of the integrated device. The coaxial structure reduces the complexity of design and signal power loss through the integrated device, thereby reducing manufacturing cost. In particular, the coaxial structure is not subject to a low frequency limit. Accordingly, the provided integrated device is compact to provide for a greater quantity of signals that can be transmitted and/or received. Furthermore, adding other devices such as an antenna is simplified based on the modular nature of the integrated device that is afforded by the coaxial structure. Therefore, the coaxial structure described herein provides an efficient and cost-effective integrated device, for example, with an antenna.

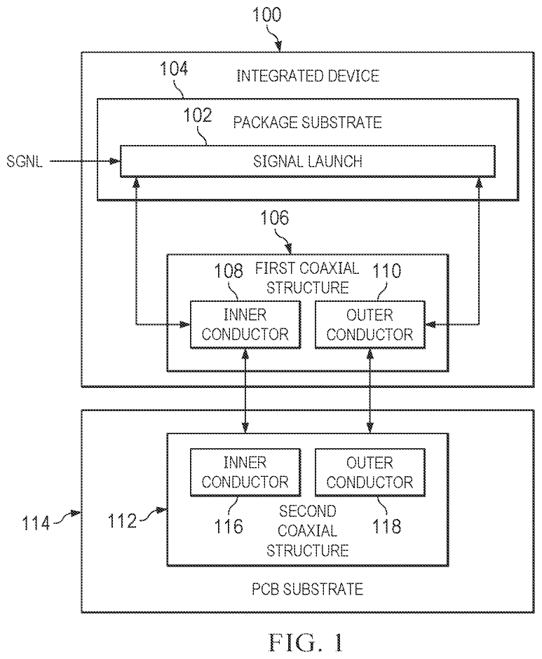

FIG. 1 illustrates an example of an integrated device 100. In one example, the integrated device 100 is a wireless communication device for emitting or receiving a signal via a signal launch 102 mounted on a package substrate 104. The package substrate 104 is silicon, silicon carbide, organic material, or other suitable material, either in substantially pure form or in combination with additional materials.

The signal is propagated to or from the signal launch 102 through a first coaxial structure 106 of the integrated device 100. The first coaxial structure 106 includes an inner conductor 108 and outer conductor 110. The signal launch 102 is electrically coupled to the inner conductor 108 of the first coaxial structure 106. The inner conductor 108 is formed of a conductive material and includes copper, aluminum, or other materials that are a suitable conductor. The outer conductor 110 of the first coaxial structure 106 is formed of a conductive material that can be the same or different than the conductive material of the inner conductor 108. The outer conductor 110 is coupled to ground. In some examples, the outer conductor 110 includes an array of grounded conductors, such as grounded solder balls or grounded vias, arranged to at least partially surround the inner conductor 108 in order to electrically isolate inner conductor 108 of the first coaxial structure 106.

The first coaxial structure 106 is adapted to be coupled to a second coaxial structure 112 of a printed circuit board (PCB) substrate 114. For example, the first coaxial structure 106 is aligned with the second coaxial structure 112. The second coaxial structure 112 includes an inner conductor 116 and an outer conductor 118. The inner conductor 116 of the second coaxial structure 112 is a signal via formed through the PCB substrate 114 that is electrically coupled to the inner conductor 108 of the first coaxial structure 106 and propagates the signal through the PCB substrate 114. The outer conductor 118 includes grounded vias formed through the PCB substrate 114 that are coupled to ground. The inner conductor 116 and the outer conductor 118 are also formed of a conductive material. The outer conductor 118 at least partially surrounds the inner conductor 116 to electrically isolate the inner conductor 116 of the second coaxial structure 112.

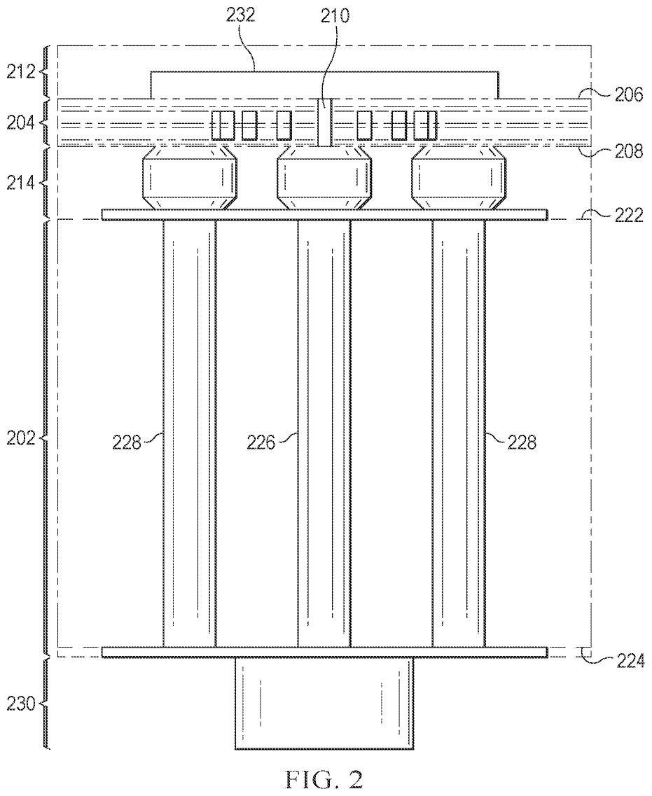

FIG. 2 illustrates another example of an integrated device 200 having a first coaxial structure and a PCB substrate 202 having a second coaxial structure. The integrated device 200 (e.g., the integrated device 100 of FIG. 1) includes a package substrate 204 (e.g., the package substrate 104 of FIG. 1) having a first substrate surface 206 opposite a second substrate surface 208. A signal launch 210 (e.g., the signal launch 102 of FIG. 1) is mounted on the first substrate surface 206 of the package substrate 204 or embedded within the package substrate 204 such that the package substrate 204 is an embedded trace substrate. In some examples, the signal launch 210 is electrically coupled to a semiconductor die 232 mounted on the first substrate surface 206. The integrated device 200 is encapsulated in a molding 212. The molding 212 is formed of an insulating material, such as organic resins, inorganic resins, or other suitable material. In some examples, the molding 212 is omitted.

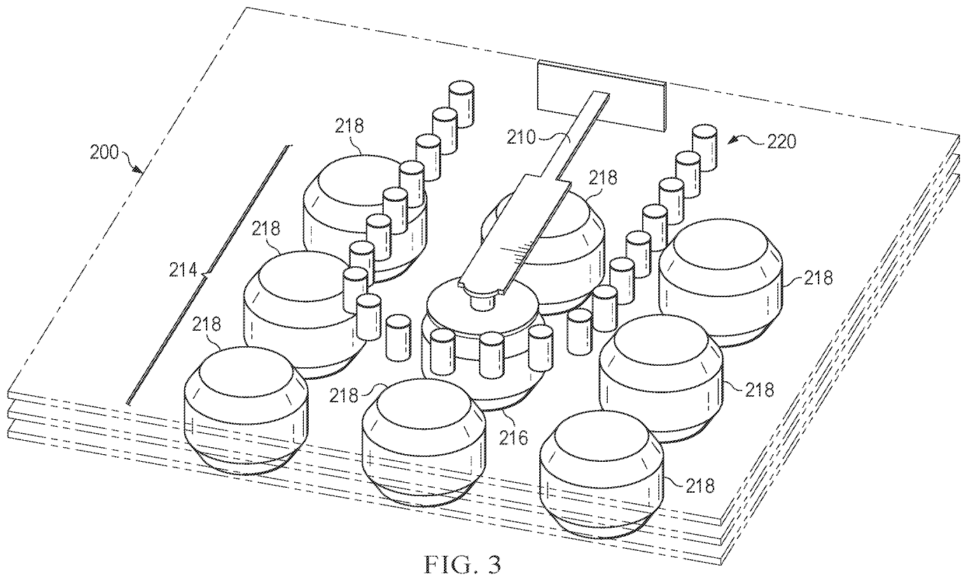

A signal is propagated to or from the signal launch 210 through a first coaxial structure 214 (e.g., the first coaxial structure 106 of the example of FIG. 1) is mounted to the second substrate surface 208 of the package substrate 204. In some examples, the first coaxial structure 214 includes a ball grid array (BGA) of solder balls. Turning to the example of FIG. 3, which illustrates a top view of the integrated device shown in the example of FIG. 2, the first coaxial structure 214 includes nine solder balls arranged in three rows and three columns.

A signal solder ball 216 of the BGA is affixed to the package substrate 204 and is an inner conductor (e.g., the inner conductor 108 of FIG. 1) to propagate the signal. In some examples, the signal launch 210 is an embedded trace in the package substrate 204 that electrically couples the integrated device 200 and the signal solder ball 216, as the inner conductor. The signal solder ball 216 is partially surrounded by a set of grounded solder balls 218 of the BGA. The set of grounded solder balls 218 are affixed to the second substrate surface 208 of the package substrate 204 and act as an outer conductor (e.g., the outer conductor 110 of FIG. 1). Thus, the signal solder ball 216 is the inner conductor and the set of grounded solder balls 218 are arranged as the outer conductor that is electrically isolated from the signal solder ball 216.

In some examples, the signal launch 210 is included in the inner conductor and a set of shielding vias 220 are included in the outer conductor. The set of shielding vias 220 are arranged to at least partially surround the signal launch 210 to establish shielding for the signal launch 210. The shielding vias 220 are also formed of a conductive material.

Returning to FIG. 2, the PCB substrate 202 has a first PCB surface 222 opposite the second PCB surface 224. The integrated device 200 is coupled to the PCB substrate 202 by the nine solder balls arranged in three rows and three columns of the first coaxial structure 214. The nine solder balls of the first coaxial structure 214 are aligned with a second coaxial structure including an inner conductor 226 and outer conductors 228 embedded in the PCB substrate 202. For example, the inner conductor 226 and the outer conductors 228 are formed in voids in the PCB substrate 202 as vias.

The inner conductor 226 is a signal via formed of a conductive material and includes copper, aluminum, or other metals that are a suitable conductor. The outer conductor 228 of the second coaxial structure includes grounded vias formed of a conductive material that can be the same or different than the conductive material of the inner conductor 226. The outer conductor 228 at least partially surrounds the inner conductor 226 to electrically isolate inner conductor 226 of the second coaxial structure. In some examples, the inner conductor 226 and the outer conductor 228 extend from the first PCB surface 222 to the second PCB surface 224. In other examples, the inner conductor 226 may include electrical components. For example, a series capacitor may be implemented at a point along the signal path between the first PCB surface 222 and the second PCB surface 224 to feed an antenna system 230 in a capacitive manner. As one example, the capacitor is implemented as a part of an impedance matching circuit. As another example, the capacitor is implemented at the second PCB surface 224 between the PCB substrate 202 and the antenna system 230.

The inner conductor 226 and the outer conductor 228 of the second coaxial structure are arranged to be aligned with the inner conductor, the signal solder ball 216, and outer conductor, grounded solder balls 218 of the first coaxial structure 214. The alignment of the first coaxial structure 214 and the second coaxial structure to facilitate the electrical coupling of the first coaxial structure 214 and the second coaxial structure. For example, the signal launch 210, the signal solder ball 216, and the inner conductor 226 are electrically coupled as the inner conductor of the associated first and second coaxial structures to propagate a signal. The set of grounded solder balls 218 and the outer conductors 228 are electrically coupled to ground as the outer conductor of the associated first and second coaxial structures.

An antenna system 230 is mounted to the second PCB surface 224. The antenna system 230 includes, for example, an external waveguide or an external antenna having a waveguide opening. A signal channel extends between the signal launch 210 and the antenna system 230. In one example, the antenna system 230 includes waveguide openings that reroute, fan out, split, and the like to other parts of the antenna system 230 based on the particular antenna design. In other examples, the antenna system 230 may include coaxial transmission lines, grounded coplanar waveguide, or stripline. The signal is propagated in the antenna system 230 as coaxial or transitioning from a coaxial in the PCB substrate 202 to stripline structure.

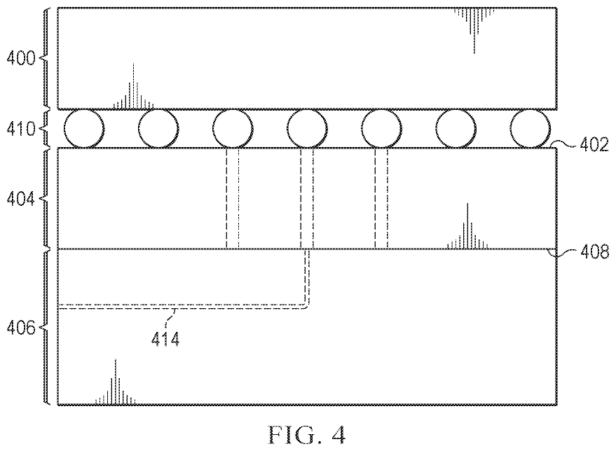

As one example shown in FIG. 4, an integrated device 400 (e.g., the integrated device 100 of FIG. 1, the integrated device 200 of FIG. 2) is mounted on a first surface 402 of a PCB substrate 404 (e.g., the PCB substrate 114 of FIG. 1, the PCB substrate 202 of FIG. 2) and an antenna system 406 (e.g., the antenna system 230 of FIG. 2) mounted on a second surface 408. As described above, the integrated device 400 includes a first coaxial structure (e.g., the first coaxial structure 106 of FIG. 1) extending from a package substrate (e.g., the package substrate 204 of FIG. 2) to a BGA 410.

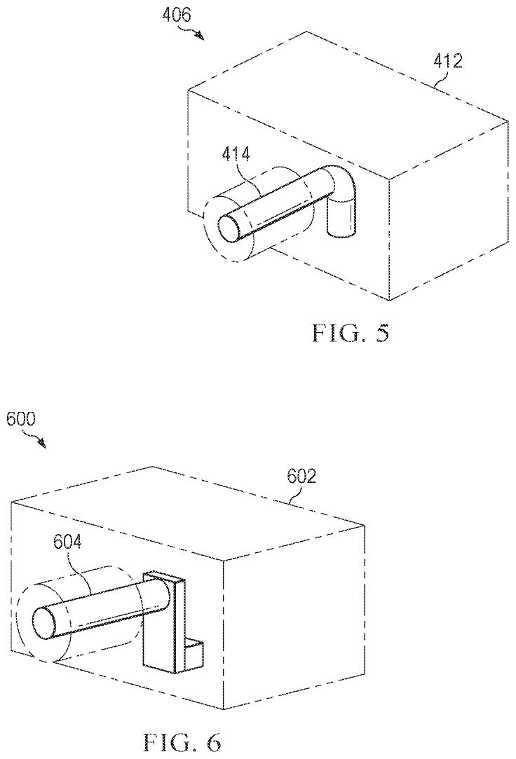

In one example, the antenna system 406 is a waveguide 412 having an L-shaped coupler 414, shown in perspective view in FIG. 5. The waveguide 412 may be a metallic waveguide, a dielectric waveguide, a dielectric filled metallic waveguide, or other waveguide suitable for propagation of signals. The L-shaped coupler 414 is fabricated as a conductor to extend from the PCB substrate 404 in order to launch signals into the waveguide 412 as a coaxial output. For example, the L-shaped coupler 414 is a shorted loop of a microstrip electrically coupled to an inner conductor (e.g., the inner conductor 226 of FIG. 2) of the PCB substrate 404. In another example, the L-shaped coupler 414 is a differential loop in which a microstrip on each side is fed differentially.

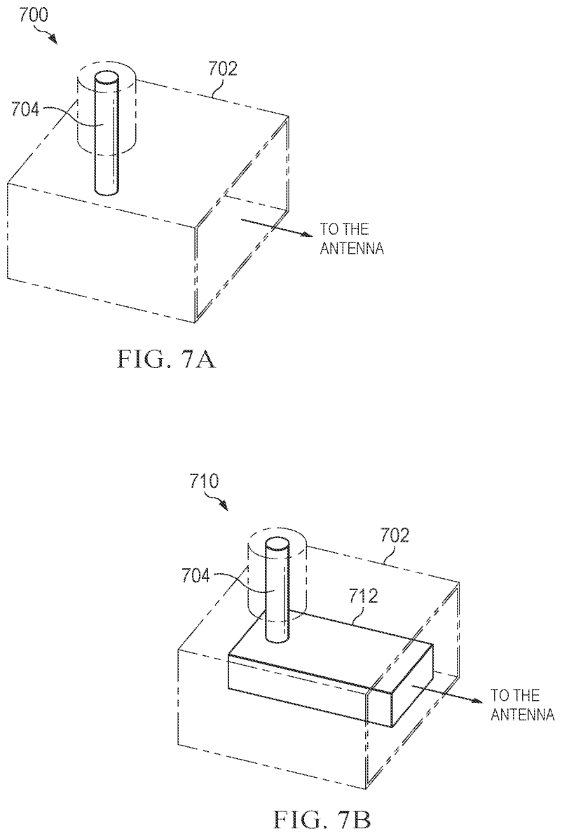

Various examples of shapes of the L-shaped coupler 414 are shown in FIGS. 6, 7A, 7B, and 8. As shown in the example of FIG. 6, an antenna system 600 (e.g., the antenna system 230 of FIG. 2, the antenna system 406 of FIG. 4) includes a waveguide 602 (e.g., the waveguide 412 of FIG. 4) and a stepped ridge coupler 604. In the example of FIG. 7A, an antenna system 700 (e.g., the antenna system 230 of FIG. 2, the antenna system 406 of FIG. 4, the antenna system 600 of FIG. 6) includes a waveguide 702 (e.g., the waveguide 412 of FIG. 4, the waveguide 602 of FIG. 6) and a linear coupler 704 as a linear coaxial output. In another example shown in FIG. 7B, an antenna system 710 includes a transmission line 712 coupled to the linear coupler 704.

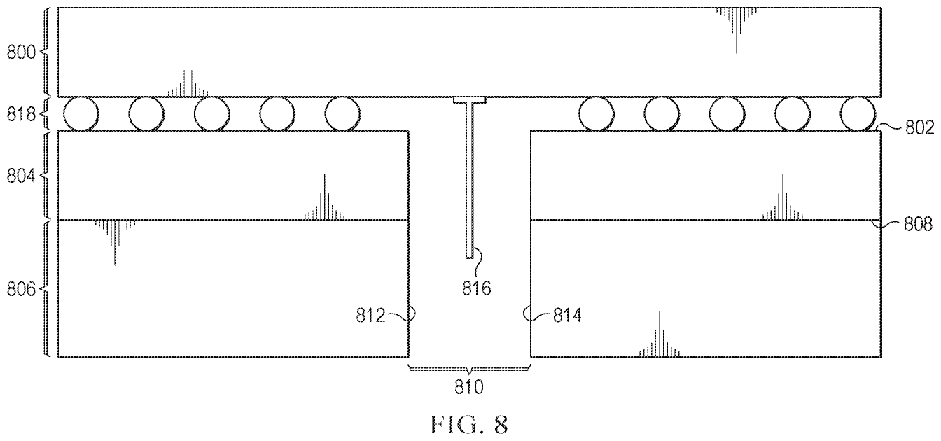

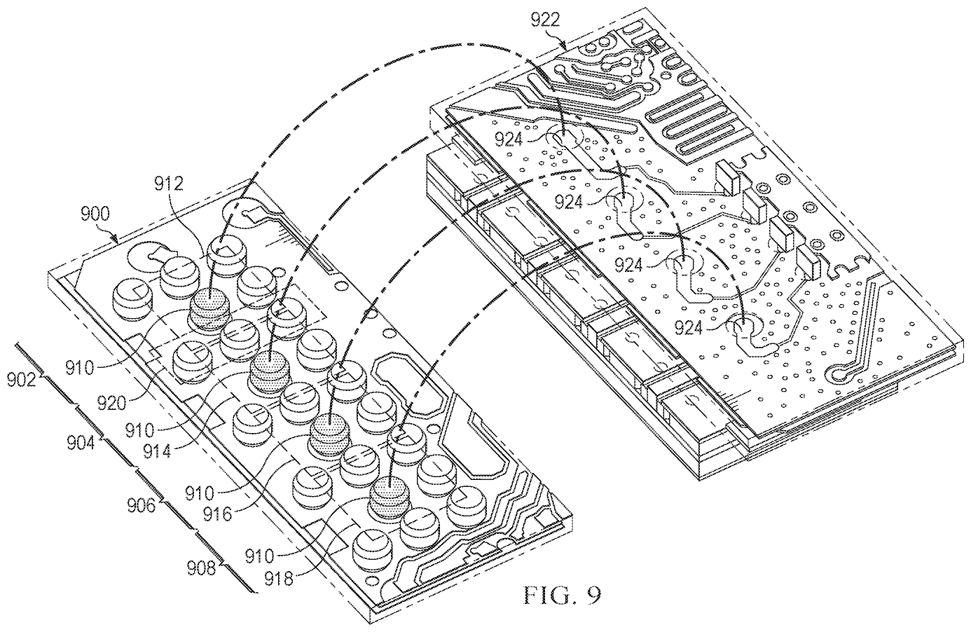

In another example, the coupler extends through the PCB substrate. As shown in the example of FIG. 8, an integrated device 800 (e.g., the integrated device 100 of FIG. 1, the integrated device 200 of FIG. 2, the integrated device 400 of FIG. 4) is mounted on a first surface 802 of a PCB substrate 804 (e.g., the PCB substrate 114 of FIG. 1, the PCB substrate 202 of FIG. 2, the PCB substrate 404) and an antenna system 806 (e.g., the antenna system 230 of FIG. 2, the antenna system 406 of FIG. 4) mounted on a second surface 808. A void 810 is formed through PCB substrate 804 and the antenna system 806. The void 810 is defined by a first continuous sidewall 812 opposite a second continuous sidewall 814. As described above, the integrated device 400 includes a first coaxial structure (e.g., the first coaxial structure 106 of FIG. 1) having a coupler 816 at least partially surrounded by a set of grounded solder balls 818 (e.g., the set of grounded solder balls 218 of FIG. 2). The coupler 816 is a conductive output pin that extends through the PCB substrate 804 in order to launch signals through the antenna system 806 as a coaxial output.

An integrated device can include a number of coaxial structures. In the example of FIG. 9, multiple sets of grounded solder balls (e.g., the set of grounded solder balls 218 of FIG. 2, the set of grounded solder balls 818 of FIG. 8) are mounted on the PCB substrate 900 (e.g., the PCB substrate 114 of FIG. 1, the PCB substrate 202 of FIG. 2, the PCB substrate 404 of FIG. 4, the PCB substrate 804 of FIG. 8). For example, the plurality of coaxial structures includes a first coaxial structure 902, a second coaxial structure 904, a third coaxial structure 906, and a fourth coaxial structure 908.

The coaxial structures 902-908 each have signal solder ball 910 (e.g., signal solder ball 216 of FIG. 2) and a respective set of grounded solder balls (e.g., the set of grounded solder balls 218 of FIG. 2, the set of grounded solder balls 818 of FIG. 8) including a first set of grounded solder balls 912, a second set of grounded solder balls 914, a third set of grounded solder balls 916, a fourth set of grounded solder balls 918. In some examples, a set of grounded solder balls includes exclusive grounded solder balls that are not common to any other sets of grounded solder balls. In other examples, the sets of grounded solder balls 912-918 include shared grounded solder balls 920 that are common to a plurality of sets of grounded solder balls 912-918. For example, the shared grounded solder balls 920 that are common to the first coaxial structure 902 and the second coaxial structure 904. In particular, the first coaxial structure 902 includes a first grounded conductor, a second grounded conductor, a third grounded conductor, a fourth grounded conductor, a fifth grounded conductor, a sixth grounded conductor, and a seventh grounded conductor. The shared grounded solder balls 920 include at least the first grounded conductor, the second grounded conductor, and the third grounded conductor.

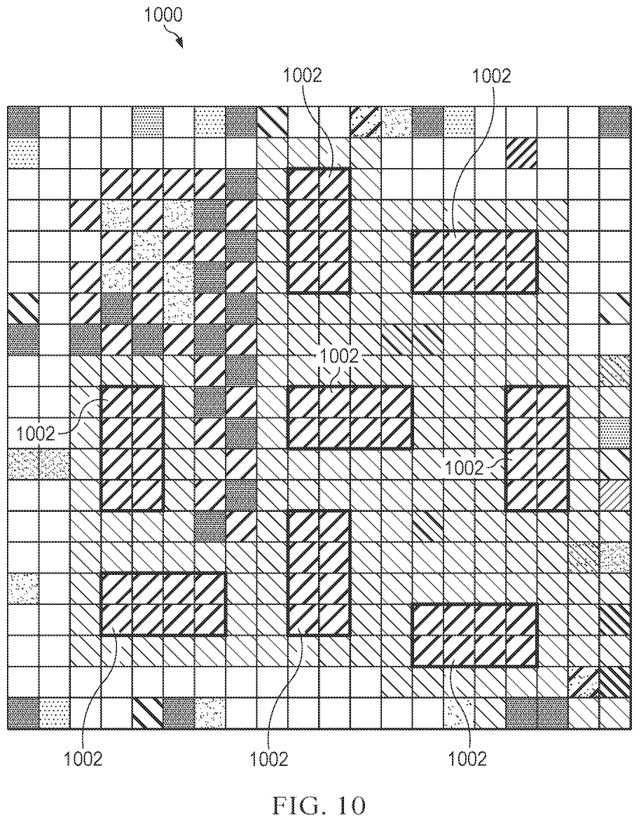

The PCB substrate 900 underlies an integrated device 922 (e.g., the integrated device 100 of FIG. 1, the integrated device 200 of FIG. 2, the integrated device 400 of FIG. 4, the integrated device 800 of FIG. 8). The signal solder balls 910 correspond to signal launches 924. In some examples, the signal launches 924 are embedded in the integrated device 922 as an embedded trace. The coaxial structures 902-908 reduce the complexity of design and signal power loss through the integrated device 922. In particular, the coaxial structures 902-908 are not subject to a low frequency limit dictated by geometry. Accordingly, the provided integrated device 922 with the coaxial structures 902-908 is compact. For example, as shown in a ball map 1000 of FIG. 10, a plurality of an integrated device 1002 can be mounted in a compact design. Therefore, the coaxial structure described herein provides an efficient and cost-effective integrated device, for example, with an antenna.

What have been described above are examples. It is, of course, not possible to describe every conceivable combination of components or methodologies, but one of ordinary skill in the art will recognize that many further combinations and permutations are possible. Accordingly, the disclosure is intended to embrace all such alterations, modifications, and variations that fall within the scope of this application, including the appended claims. As used herein, the term “includes” means includes but not limited to, the term “including” means including but not limited to. The term “based on” means based at least in part on. Additionally, where the disclosure or claims recite “a,” “an,” “a first,” or “another” element, or the equivalent thereof, it should be interpreted to include one or more than one such element, neither requiring nor excluding two or more such elements.

A “value” as used herein may include, but is not limited to, a numerical or other kind of value or level such as a percentage, a non-numerical value, a discrete state, a discrete value, a continuous value, among others. The term “value of X” or “level of X” as used throughout this detailed description and in the claims refers to any numerical or other kind of value for distinguishing between two or more states of X. For example, in some cases, the value of X is be given as a percentage between 0% and 100%. In other cases, the value of X could be a value in the range between 1 and 10. In still other cases, the value of X is not be a numerical value, but could be associated with a given discrete state, such as “not X”, “slightly x”, “x”, “very x” and “extremely x”.

In this description, unless otherwise stated, “about,” “approximately” or “substantially” preceding a parameter means being within +/−10 percent of that parameter. Modifications are possible in the described embodiments, and other embodiments are possible, within the scope of the claims.

Further, unless specified otherwise, “first”, “second”, or the like are not intended to imply a temporal aspect, a spatial aspect, an ordering, etc. Rather, such terms are merely used as identifiers, names, etc. for features, elements, items, etc. For example, a first channel and a second channel generally correspond to channel A and channel B or two different or two identical channels or the same channel. Additionally, “comprising”, “comprises”, “including”, “includes”, or the like generally means comprising or including, but not limited to.

It will be appreciated that several of the above-disclosed and other features and functions, or alternatives or varieties thereof, may be desirably combined into many other different systems or applications. Also, that various presently unforeseen or unanticipated alternatives, modifications, variations or improvements therein may be subsequently made by those skilled in the art which are also intended to be encompassed by the following claims.

What is claimed is:

1. An integrated device, comprising:
a package substrate comprising an integrated die and a signal launch configured to emit or receive a signal; and
a first coaxial structure arranged partially on a surface of the package substrate, the first coaxial structure including an inner coaxial conductor electrically coupled to the signal launch and an outer coaxial conductor comprising an array of grounded conductors arranged to at least partially surround the inner coaxial conductor, the first coaxial structure being adapted to be coupled to a second coaxial structure of a printed circuit board (PCB) via the surface of the package substrate.

2. The integrated device of claim 1, wherein the first coaxial structure includes a ball grid array (BGA) having a signal solder ball affixed to the package substrate and a set of grounded solder balls affixed to the package substrate, and wherein the signal solder ball is the inner coaxial conductor and the array of grounded conductors includes the set of grounded solder balls.

3. The integrated device of claim 1, wherein the inner coaxial conductor includes the signal launch, and the outer coaxial conductor includes a set of shielding vias arranged to at least partially surround the signal launch.

4. The integrated device of claim 1, wherein the signal launch is an embedded trace in the package substrate that electrically couples the integrated die and the inner coaxial conductor.

5. The integrated device of claim 1, wherein the inner coaxial conductor includes a signal via extending through the PCB to an antenna system and the outer coaxial conductor includes grounded vias embedded in the PCB and corresponding to the grounded conductors.

6. The integrated device of claim 5, wherein the PCB is configured to be electrically coupled to the antenna system including a waveguide.

7. The integrated device of claim 1, wherein the inner coaxial conductor includes a coupler extending from the signal launch to be received by an antenna system.

8. The integrated device of claim 1, wherein the signal launch is a first signal launch, the inner coaxial conductor is a first inner conductor, and the array of grounded conductors is a first array of grounded conductors, and wherein the integrated device further comprises:
a second signal launch, of the package substrate, that is configured to emit or receive a second signal, wherein the second coaxial structure is affixed to the package substrate and includes a second inner conductor electrically coupled to the second signal launch and a second outer conductor comprising a second array of grounded conductors arranged to at least partially surround the second inner conductor.

9. The integrated device of claim 8, wherein the first array of grounded conductors includes at least a first grounded conductor, a second grounded conductor, a third grounded conductor, a fourth grounded conductor, a fifth grounded conductor, and a sixth grounded conductor, and wherein the second array of grounded conductors includes at least the first grounded conductor, the second grounded conductor, and the third grounded conductor.

10. An antenna system, comprising:
a printed circuit board (PCB), the PCB comprising a signal via and a plurality of grounded vias extending through the PCB to an antenna; and
an integrated package comprising:
a package substrate mounted to the PCB and comprising an integrated die and a signal launch configured to emit or receive a signal;
an inner coaxial conductor affixed to the package substrate and electrically coupled to the signal launch and to the signal via of the PCB; and
an outer coaxial conductor including an array of grounded conductors affixed to the package substrate and electrically coupled to the respective grounded vias of the PCB.

11. The antenna system of claim 10, wherein the outer coaxial conductor at least partially surrounds the inner coaxial conductor to form a coaxial structure.

12. The antenna system of claim 10, wherein the inner coaxial conductor is a signal solder ball of a ball grid array (BGA), and the array of grounded conductors a set of grounded solder balls of the BGA corresponding the grounded vias.

13. The antenna system of claim 10, wherein the inner coaxial conductor further comprises the signal launch and the outer coaxial conductor further comprises a set of shielding via arranged to at least partially surround the signal launch.

14. The antenna system of claim 10, wherein the signal launch is an embedded trace that electrically couples the integrated die and the inner coaxial conductor.

15. The antenna system of claim 10, wherein the PCB is configured to be electrically coupled to the antenna system including a waveguide.

16. The antenna system of claim 10, wherein the inner coaxial conductor includes a coupler extending from the signal launch to be received by the antenna system.

17. The antenna system of claim 10, wherein the signal launch is a first signal launch, the inner coaxial conductor is a first inner conductor, and the array of grounded conductors is a first array of grounded conductors, and wherein the antenna system further comprises:
a second signal launch, of the package substrate, that is configured to emit or receive a second signal, and
a second inner conductor electrically coupled to the second signal launch and a second outer conductor comprising a second array of grounded conductors arranged to at least partially surround the second inner conductor.

18. A device, comprising:
a package substrate comprising an integrated die and a signal launch on the package substrate, the signal launch being configured to emit or receive a signal; and
a coaxial structure including a ball grid array (BGA) affixed to the package substrate, the BGA comprising an inner coaxial conductor including a signal solder ball electrically coupled to the signal launch and an outer coaxial conductor comprising a set of grounded solder balls arranged to at least partially surround the inner coaxial conductor.

19. The device of claim 18, wherein the signal launch is an embedded trace that electrically couples the integrated die and the signal solder ball.

20. The device of claim 18, wherein the inner coaxial conductor further includes a signal via extending through a printed circuit board (PCB) to an antenna system and the outer coaxial conductor includes grounded vias embedded in the PCB and corresponding to the grounded solder balls.

21. An integrated device, comprising:
a printed circuit board (PCB) including an outer coaxial conductor at least partially surrounding an inner coaxial conductor to form a PCB coaxial structure, the PCB coaxial structure being adapted to be coupled to a package substrate coaxial structure arranged partially on a surface of a package substrate.

22. The integrated device of claim 21, wherein the package substrate coaxial structure is a first coaxial structure including an inner coaxial conductor electrically coupled to a signal launch and an outer coaxial conductor comprising an array of grounded conductors arranged to at least partially surround the inner coaxial conductor.

23. The integrated device of claim 22, wherein the first coaxial structure includes a ball grid array (BGA) having a signal solder ball affixed to the package substrate and a set of grounded solder balls affixed to the package substrate, and wherein the signal solder ball is the inner coaxial conductor and the array of grounded conductors includes the set of grounded solder balls.
